(19) United States
(12) Patent Application Publication
(10) Pub. No.: US 2026/0068244 A1
(43) Pub. Date: Mar. 5, 2026

(54) SEMICONDUCTOR DEVICE INCLUDING A SUPERLATTICE PROVIDING METAL WORK FUNCTION TUNING

(71) Applicant: ATOMERA INCORPORATED, Los Gatos, CA (US)

(72) Inventors: Robert J. MEARS, Wellesley, MA (US); Hideki Takeuchi, San Jose, CA (US)

(21) Appl. No.: 19/328,693

(22) Filed: Sep. 15, 2025

Related U.S. Application Data
(63) Continuation of application No. 17/663,852, filed on May 18, 2022, now Pat. No. 12,439,658.
(60) Provisional application No. 63/189,909, filed on May 18, 2021.
(60) Provisional application No. 63/211,174, filed on Jun. 16, 2021.
(60) Provisional application No. 63/212,292, filed on Jun. 18, 2021.

(51) Int. Cl. H10D 62/10; H10D 30/01; H10D 30/67; H10D 30/69; H10D 62/815; H10D 84/01; H10D 84/03

(52) U.S. Cl. CPC H10D 62/118; H10D 30/031; H10D 30/6713; H10D 30/6735; H10D 30/6757; H10D 30/751; H10D 30/791; H10D 62/815; H10D 62/8171; H10D 84/0128; H10D 84/013; H10D 84/038

(57) ABSTRACT

A semiconductor gate-all-around (GAA) device may include a semiconductor substrate, source and drain regions on the semiconductor substrate, a plurality of semiconductor nanostructures extending between the source and drain regions, a gate surrounding the plurality of semiconductor nanostructures in a gate-all-around arrangement, and a dopant diffusion liner adjacent at least one of the source and drain regions and comprising a first superlattice. The first superlattice may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

### CROSS-REFERENCE TO RELATED APPLICATIONS

This application claims the benefit of U.S. provisional application nos. 63/189,909 filed May 18, 2021; 63/211,174 filed Jun. 16, 2021; and 63/212,292 filed Jun. 18, 2021, all of which are hereby incorporated herein in their entireties by reference.

### TECHNICAL FIELD

The present disclosure generally relates to semiconductor devices and, more particularly, to semiconductor devices including nanostructures and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A semiconductor gate-all-around (GAA) device may include a semiconductor substrate, source and drain regions on the semiconductor substrate, a plurality of semiconductor nanostructures extending between the source and drain regions, a gate surrounding the plurality of semiconductor nanostructures in a gate-all-around arrangement, and a dopant diffusion liner adjacent at least one of the source and drain regions and comprising a first superlattice. The first superlattice may include a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

In an example implementation, the dopant diffusion liner may comprise respective portions adjacent each of the source and drain regions. In some embodiments, the semiconductor device may further include a second superlattice within at least one of the nanostructures. The second superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions.

In accordance with another example implementation, the semiconductor device may further include a third superlattice embedded in the semiconductor substrate extending between the source and drain regions. The third superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions.

In still another example embodiment, the semiconductor device may further include a fourth superlattice on the semiconductor substrate beneath the source region. The fourth superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions.

In yet another implementation, the semiconductor device may further include a fifth superlattice on the semiconductor substrate beneath the drain region. The fifth superlattice may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions.

By way of example, the gate may comprise a metal. Also by way of example, the base semiconductor portion may comprise silicon, and the at least one non-semiconductor monolayer may comprise oxygen.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4A is a graph of the calculated band structure from the gamma point (G) for both bulk silicon as in the prior art, and for the 4/1 Si/O superlattice as shown in FIGS. 1-2.

FIG. 4B is a graph of the calculated band structure from the Z point for both bulk silicon as in the prior art, and for the 4/1 Si/O superlattice as shown in FIGS. 1-2.

FIG. 4C is a graph of the calculated band structure from both the gamma and Z points for both bulk silicon as in the prior art, and for the 5/1/3/1 Si/O superlattice as shown in FIG. 3.

FIG. 5 is a schematic block diagram of a gate all around (GAA) semiconductor device in accordance with an example embodiment.

FIG. 6 is a cross-sectional diagram of the GAA device of FIG. 5 taken along line B-B.

FIG. 7 is a cross-sectional diagram of the GAA device of FIG. 5 taken along line A-A.

FIG. 8 is a diagram of atomic concentration vs. voltage illustrating example threshold voltage reductions for a metal gate semiconductor device such as the GAA device of FIG. 5 in accordance with an example embodiment.

FIGS. 9A-9D are a series of cross-sectional diagrams illustrating a method for making the GAA device of FIG. 5 with superlattices in the GAA nanostructures.

FIGS. 10A-10D are a series of cross-sectional diagrams illustrating a method for making an alternative embodiment of the GAA device of FIG. 5 without superlattices in the GAA nanostructures.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to gate-all-around (GAA) semiconductor devices having one or more enhanced semiconductor superlattices therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. Applicant theorizes, without wishing to be bound thereto, that certain superlattices as described herein reduce the effective mass of charge carriers and that this thereby leads to higher charge carrier mobility. Effective mass is described with various definitions in the literature. As a measure of the improvement in effective mass Applicants use a “conductivity reciprocal effective mass tensor”,

$${M}_{e}^{- 1} and {M}_{h}^{- 1}$$

for electrons and holes respectively, defined as:

$${M}_{e , i , j}^{- 1} ( {E}_{F} , T ) = \frac{{\sum }_{E > {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E > {E}_{F}} {\int }_{B . Z .} f ( E ( k , n ) , {E}_{F} , T ) {d}^{3} k}$$

for electrons and:

$${M}_{h , i , j}^{- 1} ( {E}_{F} , T ) = \frac{- {\sum }_{E > {E}_{F}} {\int }_{B . Z .} {( {∇}_{k} E ( k , n ) )}_{i} {( {∇}_{k} E ( k , n ) )}_{j} \frac{\partial f ( E ( k , n ) , {E}_{F} , T )}{\partial E} {d}^{3} k}{{\sum }_{E > {E}_{F}} {\int }_{B . Z .} ( 1 - f ( E ( k , n ) , {E}_{F} , T ) ) {d}^{3} k}$$

for holes, where f is the Fermi-Dirac distribution, E_{F} is the Fermi energy, T is the temperature, E(k,n) is the energy of an electron in the state corresponding to wave vector k and the n^{th} energy band, the indices i and j refer to Cartesian coordinates x, y and z, the integrals are taken over the Brillouin zone (B.Z.), and the summations are taken over bands with energies above and below the Fermi energy for electrons and holes respectively.

Applicant's definition of the conductivity reciprocal effective mass tensor is such that a tensorial component of the conductivity of the material is greater for greater values of the corresponding component of the conductivity reciprocal effective mass tensor. Again Applicant theorizes without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

Applicant has identified improved materials or structures for use in semiconductor devices. More specifically, Applicant has identified materials or structures having energy band structures for which the appropriate conductivity effective masses for electrons and/or holes are substantially less than the corresponding values for silicon. In addition to the enhanced mobility characteristics of these structures, they may also be formed or used in such a manner that they provide piezoelectric, pyroelectric, and/or ferroelectric properties that are advantageous for use in a variety of different types of devices, as will be discussed further below.

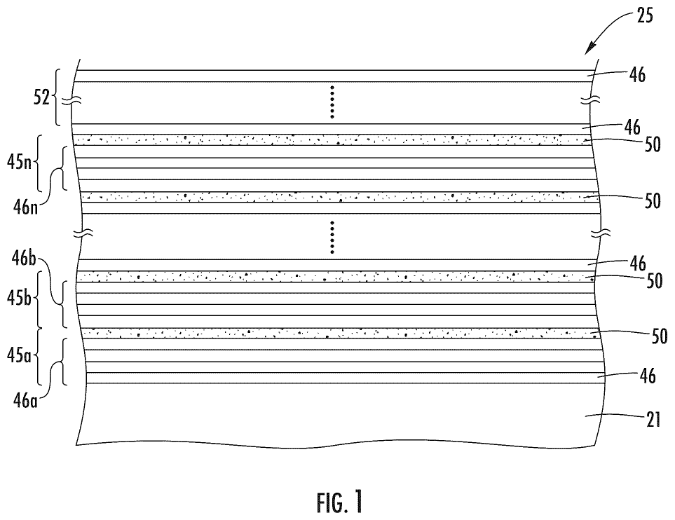

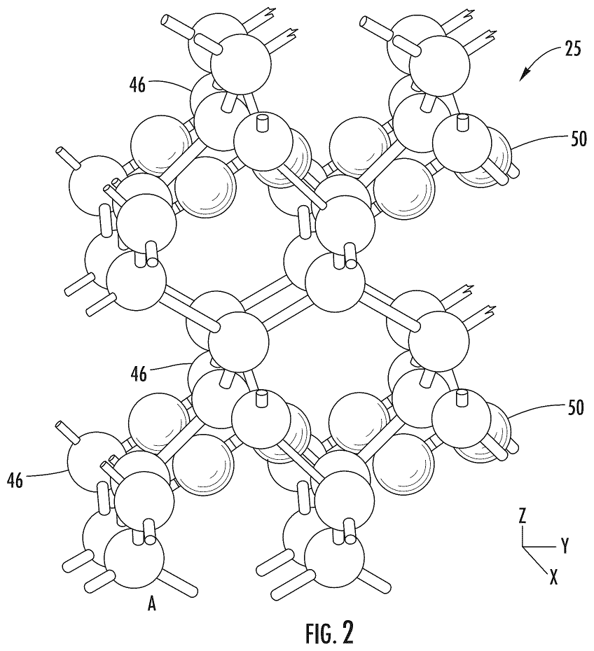

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and an energy band-modifying layer 50 thereon. The energy band-modifying layers 50 are indicated by stippling in FIG. 1 for clarity of illustration.

The energy band-modifying layer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example

It should be noted that the term monolayer is meant to include a single atomic layer and also a single molecular layer. It is also noted that the energy band-modifying layer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

It is theorized without Applicant wishing to be bound thereto that for a superlattice, such as the Si/O superlattice, for example, that the number of silicon monolayers should desirably be seven or less so that the energy band of the superlattice is common or relatively uniform throughout to achieve the desired advantages. The 4/1 repeating structure shown in FIGS. 1 and 2, for Si/O has been modeled to indicate an enhanced mobility for electrons and holes in the X direction. For example, the calculated conductivity effective mass for electrons (isotropic for bulk silicon) is 0.26 and for the 4/1 SiO superlattice in the X direction it is 0.12 resulting in a ratio of 0.46. Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons and holes, or just one of these types of charge carriers as will be appreciated by those skilled in the art.

The lower conductivity effective mass for the 4/1 Si/O embodiment of the superlattice 25 may be less than two-thirds the conductivity effective mass than would otherwise occur, and this applies for both electrons and holes. Of course, the superlattice 25 may further comprise at least one type of conductivity dopant therein, as will also be appreciated by those skilled in the art.

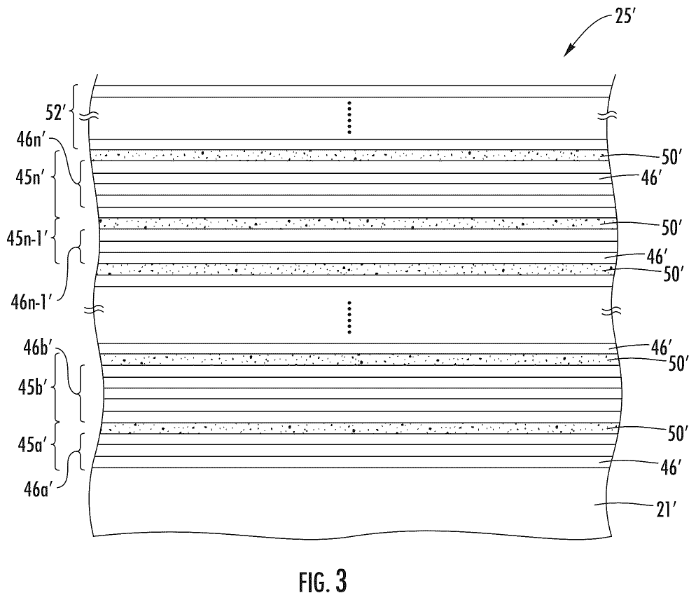

Indeed, referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

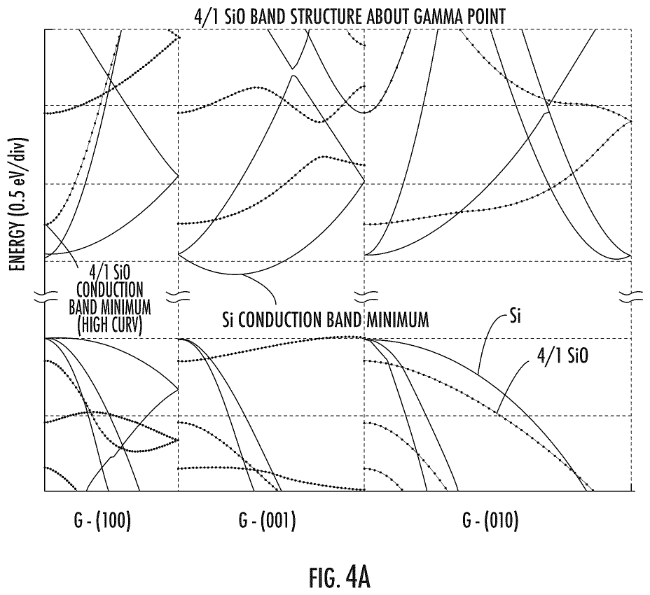

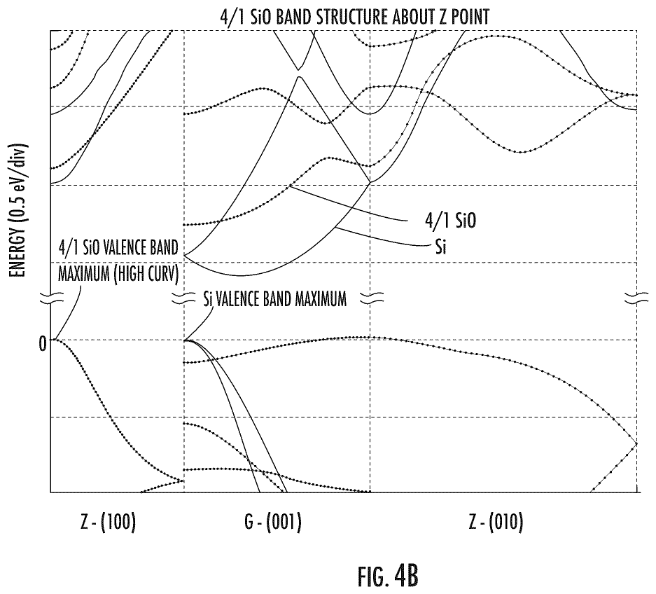

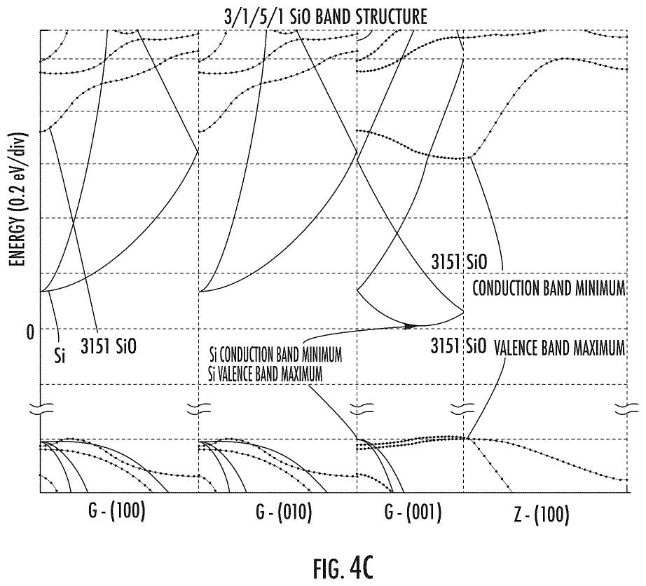

In FIGS. 4A-4C, band structures calculated using Density Functional Theory (DFT) are presented. It is well known in the art that DFT underestimates the absolute value of the bandgap. Hence all bands above the gap may be shifted by an appropriate “scissors correction.” However the shape of the band is known to be much more reliable. The vertical energy axes should be interpreted in this light.

FIG. 4A shows the calculated band structure from the gamma point (G) for both bulk silicon (represented by continuous lines) and for the 4/1 Si/O superlattice 25 shown in FIG. 1 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 4B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 4C shows the calculated band structure from both the gamma and Z point for both bulk silicon (continuous lines) and for the 5/1/3/1 Si/O structure of the superlattice 25′ of FIG. 3 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/O example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicant to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

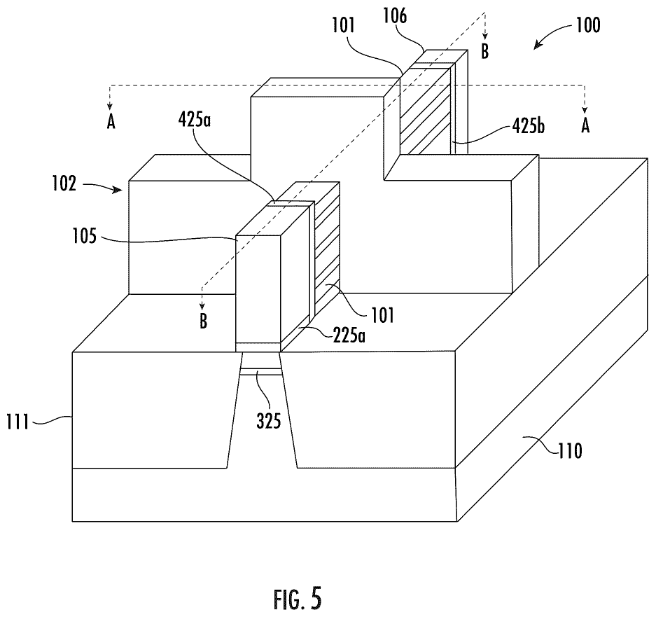

Referring now to FIGS. 5-8, the above-described superlattice structures may advantageously be used to provide enhanced metal work function tuning in semiconductor devices, such as a gate-all-around (GAA) device 100, for example. More particularly, in the illustrated GAA device 100, nanostructures (here nanosheets 101) are surrounded on all sides by a gate 102 including a high K dielectric 103 and a metal electrode 104. In other embodiments, the nanostructures may take the form of nanoparticles, nanowires, nanofibers, nanotubes, nanobelts, nanoribbons, nanodiscs, nanoplatelets, or nanohorns, and such nanostructures generally have a thickness or diameter in a range of 0.5 nm to 100 nm, for example, although other dimensions may be used in different embodiments. The channel of the GAA device 100 extends through the nanosheets 101 between source and drain regions 105, 106.

Generally speaking, GAA devices not only provide for more efficient utilization of device real estate for higher device densities, they may also help reduce problems associated with channel width variations, such as variability and mobility loss. However, in conventional GAA devices, the threshold voltage (Vt) may need to be controlled by the metal work function of the electrode metal. Typically, this involves adjusting the thickness of the metal, with thicker metal providing higher Vt values, and thinner metal providing lower Vt values. However, GAA structures may be space constrained, such that there is not enough room available for low Vt (high thickness) metals, as this would limit the number of nanosheets 101 that could otherwise be placed in the gate stack. Since drive current is proportional to the number of nanosheets 101 present, use of low Vt (high thickness) metal may otherwise lead to an undesirable decrease in drive current for low Vt devices. By way of background, U.S. Pat. Pub. No. 2021/0126018 to Zhang et al., which is hereby incorporated herein in its entirety by reference, discloses one approach to implementing a GAA device in which the Vt is shifted based on a thickness of a portion of the dielectric layer.

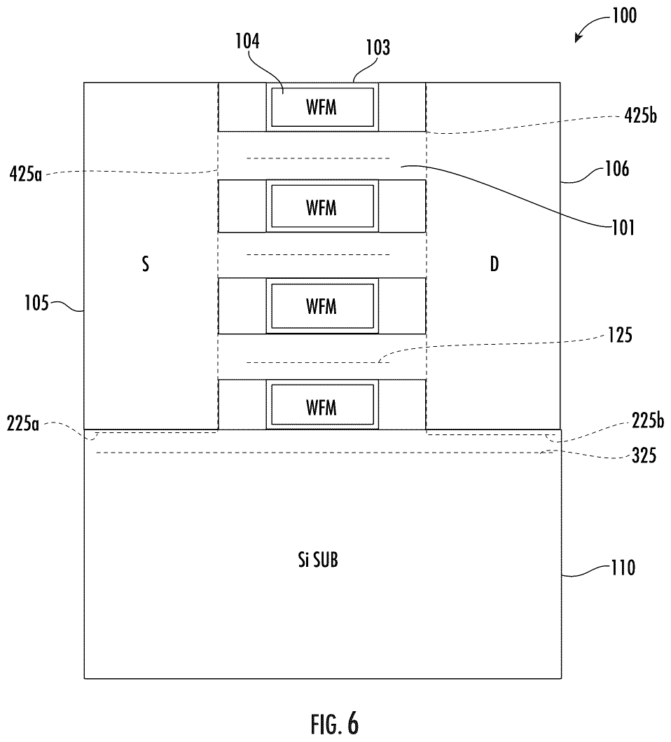

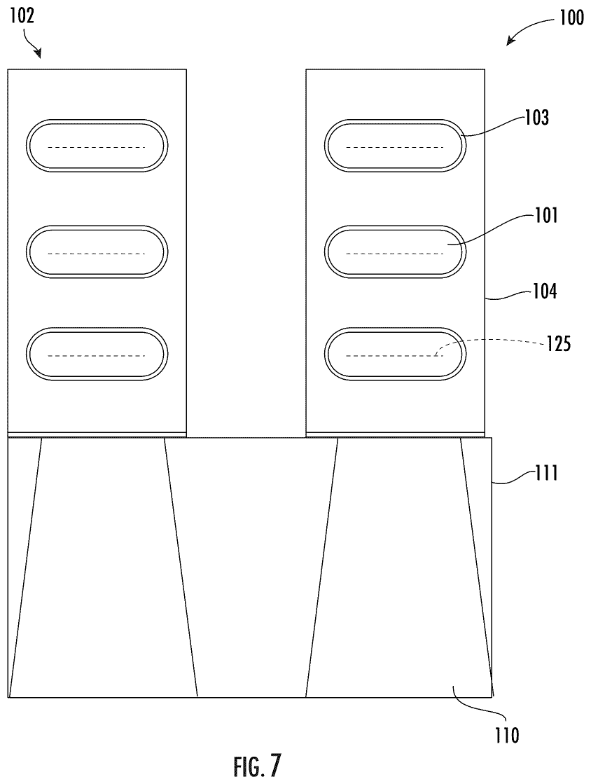

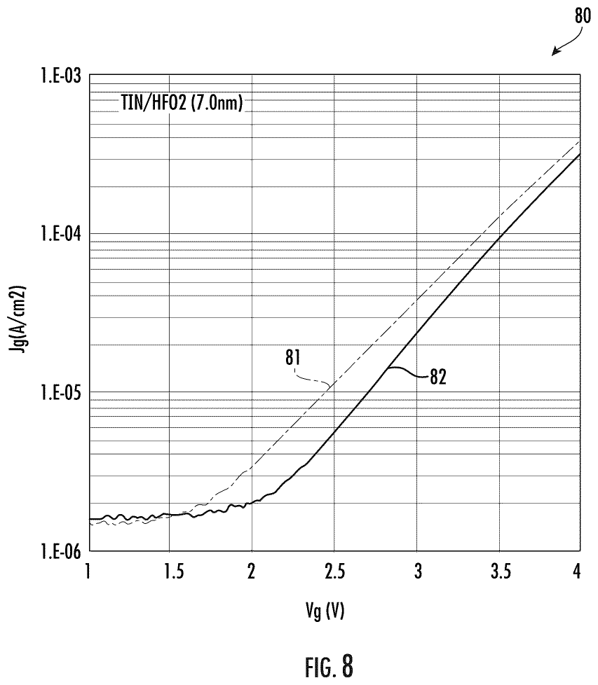

In the present example, one or more inserted non-semiconductor (e.g., oxygen) monolayers 50 or full MST films 125 may be incorporated within the nanosheets of a GAA device to advantageously provide desired work function tuning (see FIGS. 6 and 7). As shown in the diagram 80 of FIG. 8, simulation results establish that incorporation of one or more non-semiconductor monolayers within a nanosheet advantageously lowers Vt vs. a pure silicon nanosheet, such that a relatively thin metal thickness may be used without resulting in the otherwise high Vt that would accompany the relatively low metal thickness. In the illustrated example, respective plots 81, 82 illustrate voltage per atomic area using an MST film vs. straight silicon with a TiN/HfO2 gate configuration having a 7 nm thickness for the simulations. However, it will be appreciated that other gate materials and configurations may be used in different embodiments.

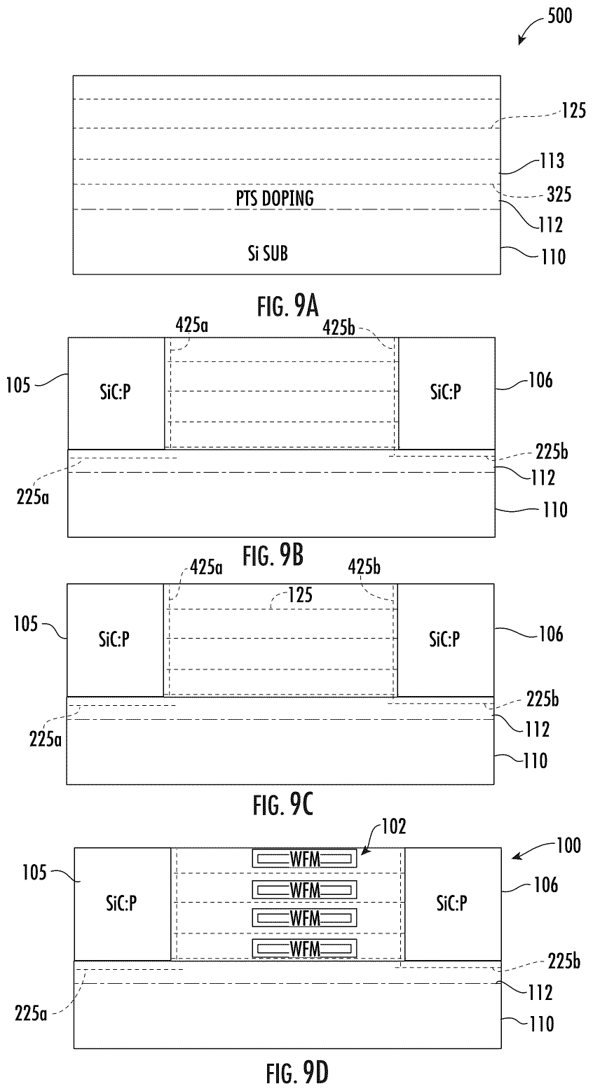

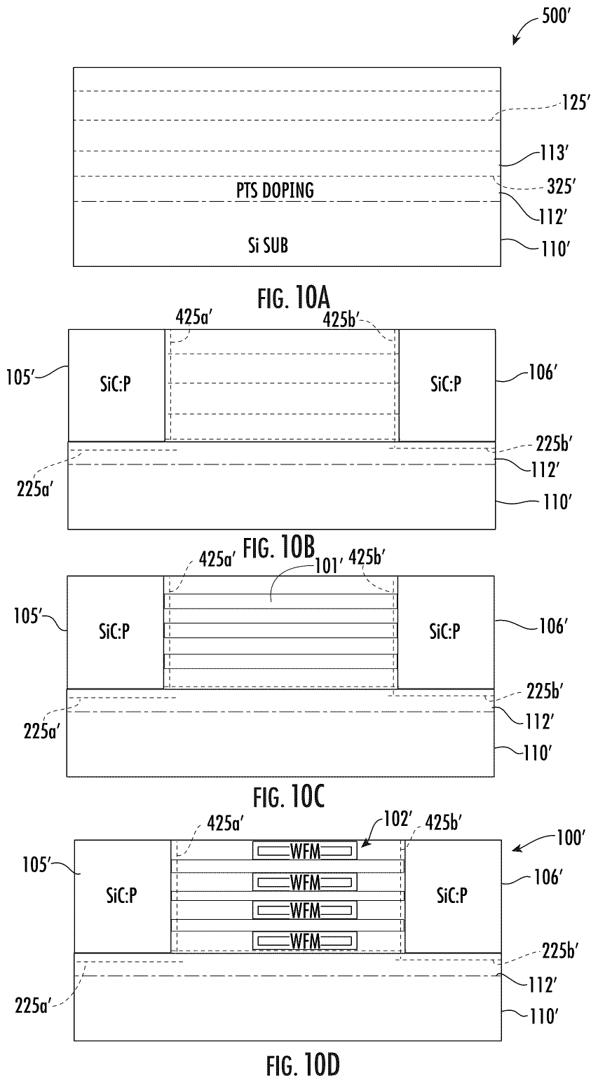

In this way, for integrated circuits where both high and low Vt devices are required, similar structures may be used for both, just with the inclusion of an inserted oxygen (or MST) layer within the nanosheets of the low Vt devices. Processes for making high and low Vt GAA devices with and without inserted oxygen/MST layers in the nanosheets 100 will be discussed below with reference to FIGS. 9A-9D and 10A-10D, respectively. It should be noted that one or more inserted oxygen (or MST) layers may be at different locations within the nanosheets, such as at the top and/or bottom interfaces, as well as in the middle of the nanosheet. Further details regarding the incorporation of inserted oxygen/MST layers in nanostructures are provided in U.S. Pat. Pub. No. 2022/0005926 to Weeks et al., which is assigned to the present Applicant and hereby incorporated herein in its entirety by reference.

As also seen in FIG. 6, inserted oxygen (or MST) layers 225a and/or 225b may additionally (or instead) be incorporated on the surface of the substrate 110 (here a silicon substrate) below the source and/or drain 105, 106, respectively, to advantageously provide a punch through stop (PTS) layer to help avoid source/drain dopant punch through. Moreover, an inserted oxygen (or MST) layer 325 may additionally (or instead) be positioned in the substrate 110 as a PTS layer extending between the source and drain 105, 106, either individually or in conjunction with the layers 225a and/or 225b. In the illustrated example, shallow trench isolation (STI) regions 111 (e.g., SiO₂) are used to electrically isolate different devices across the substrate 110.

Also in the illustrated example, a respective dopant diffusion liner 425a, 425b (which may be an inserted oxygen or MST layer) is located between the source 105 and the gate 102 and/or between the drain 106 and the gate, respectively, as shown to advantageously help prevent dopant diffusion from the source/drain regions to the nanosheets 101. Further information regarding the use of MST layers as PTS layers and for dopant diffusion blocking are set forth in U.S. Pat. Nos. 9,941,359 and 9,899,479, which are both assigned to the present Applicant and hereby incorporated herein in their entireties by reference. MST films used for the various layers 125, 225a, 225b, 325, 425a, and 425b may be similar to those described above with reference to FIGS. 1-4c, as well as in U.S. Pat. Pub. No. 2022/0005926 noted above, for example.

Referring now additionally to the process flow diagrams 500, 500′ of FIGS. 9A-9D and 10A-10D, example methods for fabricating low and high Vt GAA devices 100, 100′ with superlattices 125 in the nanosheets 101 and without, respectively, are now described. In step (a) of both process flows, a PTS implant 112 or 112′ is formed in the substrate 110 or 110′. This is followed by the formation of the PTS layer 325 or 325′ and nanosheet epitaxy with epitaxial silicon germanium (SiGe) 113 or 113′ deposition with vertically spaced silicon/oxygen superlattice layers 125 or 125′ therein. In step (b), the regions where the sources 105 or 105′ and drains 106 or 106′ are to be formed may then be etched away to define the nanosheet “fin” and provide pattering for the formation of the STI regions 111, as well as dummy gate patterning. The respective MST layers 225a, 225b or 225a′, 225b′ may then be formed on the surface of the substrate 110 or 110′, and the vertical MST dopant diffusion liners 425a, 425b or 425a′, 425b′ may be formed on the source or drain side of the SiGe 113 or 113′, respectively, followed by growth of the source/drain regions 105, 106 or 105′, 106′. In the illustrated example, a doped SiC:P epitaxy may be performed to grow the source and drain regions 105, 106 or 105′, 106′. This may be performed using a cluster tool to perform the etch+ash+clean operations, as well as the epitaxial growth, as will be appreciated by those skilled in the art.

In step (c) of both process flows 500, 500′, the SiGe sacrificial layer 113 or 113′ is removed. However, for the high Vt GAA device 100′, a high temperature anneal (e.g., 5 s-120 s at 800-1000 C in N₂ or O₂ or UHV) is also performed to cause the oxygen from the MST layers 125′ to diffuse out (i.e., the MST layers are no longer present in the nanosheets 101′). Further details on annealing to out-diffuse oxygen from an MST layer may be found in U.S. Pat. No. 10,109,479 to Mears et al., which is assigned to the present Applicant and hereby incorporated herein in its entirety by reference. Here again, this processing may also be performed using a cluster tool. Both process flows conclude with the formation of the high K metal gate (HKMG) gate 102 or 102′ in step (d).

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included.

1-21. (canceled)

22. A semiconductor gate-all-around (GAA) device comprising:
source and drain regions;
a plurality of semiconductor nanostructures extending between the source and drain regions;
a gate surrounding the plurality of semiconductor nanostructures in a gate-all-around arrangement; and
a first superlattice adjacent at least one of the source and drain regions and comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

23. The semiconductor device of claim 22 wherein the first superlattice comprises respective portions adjacent each of the source and drain regions.

24. The semiconductor device of claim 22 further comprising a second superlattice within at least one of the nanostructures, the second superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

25. The semiconductor device of claim 22 further comprising a semiconductor substrate and a third superlattice embedded in the semiconductor substrate extending between the source and drain regions, the third superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

26. The semiconductor device of claim 22 further comprising a semiconductor substrate and a fourth superlattice on the semiconductor substrate beneath the source region, the fourth superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

27. The semiconductor device of claim 22 further comprising a semiconductor substrate and a fifth superlattice on the semiconductor substrate beneath the drain region, the fifth superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

28. The semiconductor device of claim 22 wherein the gate comprises a metal.

29. The semiconductor device of claim 22 wherein the base semiconductor portion comprises silicon.

30. The semiconductor device of claim 22 wherein the at least one non-semiconductor monolayer comprises oxygen.

31. A semiconductor gate-all-around (GAA) device comprising:
source and drain regions;
a plurality of semiconductor nanostructures extending between the source and drain regions;
a gate surrounding the plurality of semiconductor nanostructures in a gate-all-around arrangement;
a first superlattice adjacent respective portions of the source and drain regions and each comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
a second superlattice within at least one of the nanostructures, the second superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

32. The semiconductor device of claim 31 further comprising a semiconductor substrate and a third superlattice embedded in the semiconductor substrate extending between the source and drain regions, the third superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

33. The semiconductor device of claim 31 further comprising a semiconductor substrate and a fourth superlattice on the semiconductor substrate beneath the source region, the fourth superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

34. The semiconductor device of claim 31 further comprising a semiconductor substrate and a fifth superlattice on the semiconductor substrate beneath the drain region, the fifth superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

35. The semiconductor device of claim 31 wherein the gate comprises a metal.

36. A semiconductor gate-all-around (GAA) device comprising:
source and drain regions;
a plurality of semiconductor nanostructures extending between the source and drain regions;
a gate surrounding the plurality of semiconductor nanostructures in a gate-all-around arrangement; and
a first superlattice adjacent at least one of the source and drain regions and comprising a plurality of stacked groups of layers, each group of layers comprising a plurality of stacked silicon monolayers defining a base silicon portion, and at least one oxygen monolayer constrained within a crystal lattice of adjacent base silicon portions.

37. The semiconductor device of claim 36 wherein the first superlattice comprises respective portions adjacent each of the source and drain regions.

38. The semiconductor device of claim 36 further comprising a second superlattice within at least one of the nanostructures, the second superlattice comprising a plurality of stacked groups of layers, each group of layers comprising a plurality of stacked base silicon monolayers defining a base semiconductor portion, and at least one oxygen monolayer constrained within a crystal lattice of adjacent base silicon portions.

39. The semiconductor device of claim 36 further comprising a semiconductor substrate and a third superlattice embedded in the semiconductor substrate extending between the source and drain regions, the third superlattice comprising a plurality of stacked groups of layers, each group of layers comprising a plurality of stacked base silicon monolayers defining a base silicon portion, and at least one oxygen monolayer constrained within a crystal lattice of adjacent base silicon portions.

40. The semiconductor device of claim 36 further comprising a semiconductor substrate and a fourth superlattice on the semiconductor substrate beneath the source region, the fourth superlattice comprising a plurality of stacked groups of layers, each group of layers comprising a plurality of stacked base silicon monolayers defining a base silicon portion, and at least one oxygen monolayer constrained within a crystal lattice of adjacent base silicon portions.

41. The semiconductor device of claim 36 further comprising a semiconductor substrate and a fifth superlattice on the semiconductor substrate beneath the drain region, the fifth superlattice comprising a plurality of stacked groups of layers, each group of layers comprising a plurality of stacked base silicon monolayers defining a base silicon portion, and at least one oxygen monolayer constrained within a crystal lattice of adjacent base silicon portions.

42. The semiconductor device of claim 36 wherein the gate comprises a metal.
